(19) United States
(12) Patent Application Publication
(10) Pub. No.: US 2004/0029048 A1
(43) Pub. Date: Feb. 12, 2004

(54) Method for the production of screen cavities in a rotogravure form and base body applicable in said method

(76) Inventor: Jakob Frauchiger, Hilterfingen (CH)

Correspondence Address: Jacox Meckstroth & Jenkins, 2310 Far Hills Building, Dayton, OH, 45419-1575, US

(21) Appl. No.: 10/416,706

(22) PCT Filed: Nov. 15, 2001
(86) PCT No.: PCT/CH01/00668

(30) Foreign Application Priority Data
Nov. 15, 2000 (CH) 2219/00

(51) Int. Cl. G03F 7/00; G03F 7/26

(52) U.S. Cl. 430/307

(57) ABSTRACT

The invention relates to the production of a rotogravure form, preferably comprising a rotationally symmetrical base body (1) and with screen cavities (5) as print information, by means of time-modulated, particularly pulsed laser radiation (9), whereby an erosion support layer (13) is applied to the surface regions (8), provided for information engraving on the base body (1), through which the screen cavities (5) are produced in said surface regions (8) with the laser radiation (9), by means of material ablation. Said erosion support layer (13) is subsequently removed to give burr-free screen cavities (5).

The invention relates to the method according to the preamble of patent claim 1 and to a base body for a gravure printing form according to the preamble of patent claim 8.

Prior Art

DE-A 2 218 393 discloses a method, not of the generic type, for producing gravure printing forms using electron beams. During the production of gravure printing forms with electron beams, difficulties arose in the production of engraved cells with a depth-below 10 μm. DE-A 2 218 393 therefore proposed to coat the surfaces to be engraved by electron beams with a separating layer of silver or copper sulfide with a layer thickness of only 0.1 μm. A second layer of copper with a layer thickness of 15 μm was then applied to the separating layer. The separating layer and second layer were used merely to reduce to removal depth. Following engraving with electron beams, cells with a depth of 20 μm having been produced, only cells of a depth of 5 μm; that is to say less than 10 μm, as desired, remained when the separating and copper layer were subsequently pulled off. Because of the production of two layers of different materials and operating in a vacuum, the method described in DEA 2 218 393 constituted a complicated method.

DE-A 30 35 714 discloses a further method for producing printing cells for a gravure printing form. In this case, the still “raw” gravure printing form is covered with a varnish that is resistant to etching agent. The varnish was then removed by an electronic engraving device at the points at which engraved cells were subsequently to be present. The electronic engraving device used was a stylus, a laser beam or an electron beam. Following the specific removal of the varnish, an etching process was carried out for producing engraved cells. The production method described here was complicated and time-consuming.

A method analogous to this is described in DE-A 2 344 233.

It is then proposed, in EP-B 0 473 973, to perform direct engraving of the engraved cells for the gravure printing form by means of laser radiation, reference being made here to the fact that a laser processing of gravure printing forms was associated with an outer layer of copper, with the following difficulties:

1. Very high reflection from the copper layer;

2. High melting or evaporation temperature of copper;

3. High heat of fusion or evaporation of copper;

4. Good thermal conductivity of copper and therefore high dissipation of heat to the surroundings of the engraved cells.

During laser engraving of copper layers, a projecting ejected crater edge additionally resulted on the cell. This edge then had to be removed in a laborious way.

For this reason, EP-B 0 473 973 proposes no longer producing the cells in copper but in zinc.

Although the method described in EP-B 0 473 973 can be used, it is a drawback in gravure printing forms produced in this way that the entire gravure printing technology is currently based on copper as the material in which the engraved cells are located.

### OBJECT OF THE INVENTION

It is an object of the invention to present a method and to provide a base body in which and on which engraved cells for a gravure printing form can be produced directly by means of laser radiation, preferably in copper and also in other materials, without an ejected crater edge, that is to say burr-free of the object.

The object is achieved in that an erosion support layer, preferably only a single erosion support layer, is applied to the base body over its surface regions provided for the impression of information, through which layer engraved cells are introduced into the surface regions by the laser radiation by material removal (evaporation and/or ejection of molten material), and this support layer is then removed, to give burr-free engraved cells. The laser radiation is a radiation whose intensity is modulated over time. As a rule, use is made of pulsed radiation, but this is not imperative. Laser spikes, Q-switch, mode-locking and so on are likewise possible. During the removal of the support layer, no change in the engraved cells takes place in the surface regions. The quality of the engraved cells produced in this way without burrs is so good that a hard layer, in particular a chromium layer, can be applied without post-treatment. The chromium layer in such gravure printing forms will preferably be applied in a layer thickness between 4 μm and 30 μm, in particular between 8 μm and 10 μm.

The burr-free engraved cells, preferably in copper, may be achieved in particular by the support layer being chosen such that it permits good input coupling of the energy of the laser radiation with a good material removal initiation (ablation) in relation to the material lying underneath, with minimized, directed backscatter of radiation. The minimized backscatter of radiation is important in order that no radiation gets back into the laser resonator. This is because it would be amplified there and could have the effect of damaging the optical components. Good input coupling of the energy of the laser radiation is important, since then only a small proportion of radiation still remains, which could still come into question for back reflection. On the other hand, good input coupling of energy has the effect of severely heating up the material of the support layer. Once the support layer has changed into the liquid state, radiation absorption should virtually no longer be a cause for concern.

If this material of the support layer is then chosen in such a way that, in the case of a substantial material proportion, the melting point is low, then the high radiation absorption also begins quickly. However, the melting point should in any case be lower than that of the surface material lying underneath, in which the engraved cells are then located. Should the engraved cells be located in copper, then the melting point should be below 1083° C. Merely in terms of the melting point, among the metals, silver with 961° C., aluminum with 660° C., gold with 1063° C. (but this drops out immediately from the point of view of costs), gallium and germanium with 937° C., indium with 927° C., lead with 327° C., tin with 232° C., zinc with 193° C. etc. would appear suitable. However, it is sensible to use only materials whose vapors are not damaging to health, since otherwise a great deal of effort would have to be expended for vapor extraction. A substantial proportion of the layer material is understood to mean a percentage which brings about the property listed above. A substantial proportion of material, depending on the materials, should lie around a percentage of 80 percent to virtually 100 percent.

The material of the support layer is intended to effect material removal in the material lying underneath and bearing the printing information. This means that, as a result of the local thermal energy introduced by the laser radiation, reproduced melting of the material lying underneath should take place as quickly as possible. As tests have shown, this reproducible melting is provided only if the layer thickness of the erosion support layer is equally thick everywhere. This is because, if this is the case, the cell volume to be produced can be predefined exactly via the maximum pulse intensity radiated in and the pulse shape. The cell volume may be determined most simply by experiment. Good results have been provided in the case of copper as the information-bearing layer and zinc as the erosion support layer with their layer thickness between 1 μm and 15 μm, preferably between 5 μm and 10 μm, with a layer thickness tolerance of less than 10⁻³, preferably of better than 5·10⁻⁵. A zinc layer with such an accuracy is best applied by electroplating.

By means of tests, it was further possible to establish the fact that the material of the erosion support layer should have the highest possible vapor pressure. “Background material” which is thrown out of the information-bearing layer by the laser pulse and which falls onto the support layer in still liquid form causes the latter to melt and evaporate and is then thrown off by the vapor with a further loss of heat. The vapor pressure of the “background material” should be at least five times smaller than that of the material lying on it. If the example cited above is maintained, then zinc has a vapor pressure approximately 100 times greater than copper.

The material of the erosion support layer should be capable of being removed easily, in particular chemically, without any attack of the surface regions bearing the information.

The wavelength of the laser radiation used must be matched to the absorption of the material of the erosion support layer. In addition, the wavelength must be matched with respect to the optical imaging laws to the dimensions of the engraved cells to be produced. For engraved cells with a diameter greater than 10 μm, a CO₂ laser (wavelength 10.6 μm) can be used. For small diameters, use is preferably made of an Nd: YAG laser (1.06 μm). The pulse shaping and optical construction for the beam guidance of the laser will preferably be performed in such a way as described in EP 00 810 552.0. If an Nd: YAG laser is used, zinc has also been tried and tested as the material for the erosion support layer in this case.

The erosion support layer not only initiates material removal in the material lying underneath, but additionally effects a turn-on delay for the boring operation in the layer lying underneath. The laser pulse has therefore already risen to an intensity value that is higher as compared with its pulse starting value, which results in an increase in the boring intensity. This results in a good engraved cell shape, that is to say a hemispherical shape.

Further advantages of the invention and of the design variants also emerge from the text below.

In the following text, an exemplary embodiment will be cited which, in accordance with the above explanations, can also be varied in terms of materials over a wide range.

The following details description and all the patent claims give further advantageous embodiments and combinations of features of the invention.

### BRIEF DESCRIPTION OF THE DRAWINGS

In the drawings used to explain an exemplary embodiment:

FIG. 1 shows a cross section through the base body according to the invention in an enlarged illustration with a pulsed laser beam that produces an engraved cell,

FIG. 2 shows a cross section analogous to FIG. 1, the erosion support layer having been removed here, and

FIG. 3 shows a cross section analogous to FIGS. 1 and 2, a hard layer having been applied here.

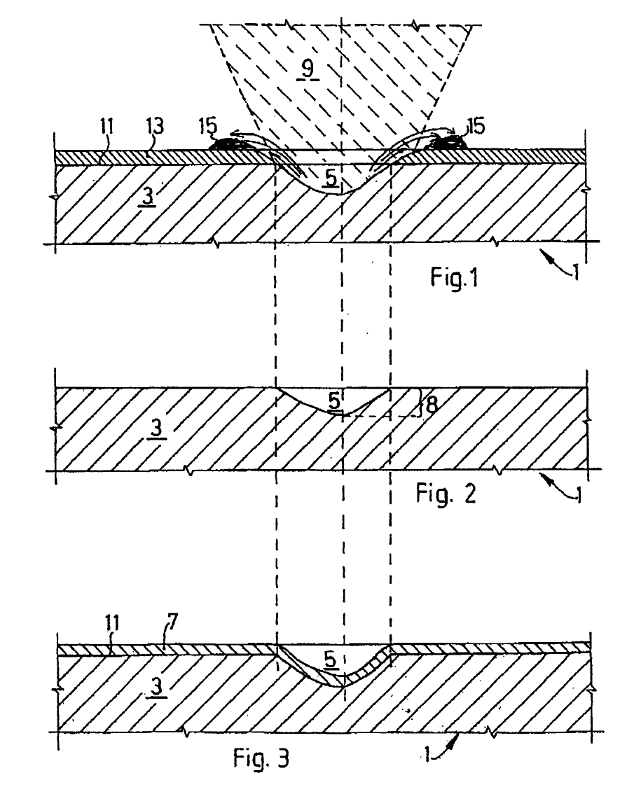

In principle, in the figures, identical parts are provided with identical reference symbols.

### Ways of Implementing the Invention

Metallic rotary gravure printing forms are normally built up from a plurality of functional elements. The base body 1 normally used is a steel cylinder. Applied to the steel cylinder is a copper layer 3 in a thickness of a few millimeters. The copper layer 3 is the information-bearing gravure printing form. The information comprises an arrangement of a large number of engraved cells 5, which accept ink needed for the printing. In order to increase the resistance, a chromium coating 7 with a typical thickness of about 10 μm is applied as the topmost layer.

The printing information is then introduced directly into the copper layer 3 in its top layer region 8 by material removal with a beam 9 from a pulsed Nd: YAG laser. In order to achieve this direct material removal with the burr-free engraved cells 5, the copper surface 11 is provided with a zinc layer 13 by electroplating, as an erosion support layer, with a low thickness tolerance (less than 5·10⁻⁵). Freedom from burrs is a precondition for satisfactory quality in the printing process.

The laser pulse 9 for producing an engraved cell 5 in each case penetrates the zinc layer 13, melting it in the process. Solid zinc has an absorption of about 50% for the radiation 9 of the Nd: YAG laser. In addition, solid zinc exhibits virtually no directed backscatter. When the zinc changes into the liquid state, on account of its relatively low melting point and its low thermal conductivity as compared with copper, virtually 100 percent radiation absorption takes place. Intense local heating of the zinc takes place, which, in the absorbent state, continues to pass said heat on to the copper lying underneath, whereupon the latter likewise changes to the liquid state. The copper then changes from virtually 100 percent reflection for the radiation 9 from the Nd: YAG laser (but the reflection not occurring, since the copper is still covered by zinc) to approximately 100 percent absorption in the now liquid state.

The ejected copper material and the ejected zinc 15 lie on the zinc layer 13 and can easily being removed, by being stripped chemically in a subsequent cleaning process. The exposed engraving (engraved cell 15) in the copper 3 is free of burrs and can be chromium-plated without difficulty.

With the thin zinc layer 13 which is then applied, economic, direct, burr-free laser engraving in the copper 3 has then become possible. Zinc in particular prevents adhesion of the molten material, reduces the initial reflection for the laser radiation 9 and therefore permits an efficient boring process in the copper 3.

The method just described is of course not restricted to zinc 13 as copper coating. As mentioned at the beginning, a series of other materials are possible. The erosion support layer to be applied to copper 3 does not necessarily have to be a metal layer either. Non-metals are also suitable, provided they have the required properties with regard to absorption, directed reflection and melting point.

Instead of only a single erosion support layer 13, a plurality of layers can also be applied one above another. However, the single zinc layer 13 has been tried and tested for reasons of costs and because of the simple handling.

The base body 1 of a gravure printing form does not necessarily have to be constructed in cylindrical form; it can also be semicylindrical, flat or otherwise shaped.

1. A method for producing engraved cells (5) as a gravure printing form bearing printing information, preferably having a rotationally symmetrical base body (1), by means of time-modulated, in particular pulsed, laser radiation (9), characterized in that on the base body (1), over its top surface regions (8) provided for information to be impressed, an erosion support layer (13) is applied, through which engraved cells (5) are introduced into the layer regions (3, 8; 13) by the laser radiation (9) by material ablation and this erosion support layer (13) is subsequently removed to give burr-free engraved cells (5).

2. The method as claimed in claim 1, characterized in that only a single erosion support layer (13) is applied and, after its removal, a hard layer (7), in particular a chromium layer (7), preferably with a layer thickness between 4 μm and 30 μm, in particular between 8 μm and 10 μm, is applied, and the layer regions (8) provided for the impression of information are preferably made of copper.

3. The method as claimed in claim 1 or 2, characterized in that the support layer (13) is selected in such a way that it permits good input coupling of energy for the laser radiation (9) with good material removal initiation in relation to the material (3,8) lying underneath with minimized directed backscatter of radiation.

4. The method as claimed in one of claims 1 to 3, characterized in that the support layer (13) is applied with a thickness that is constant apart from a tolerance, in order to be able to produce the engraved cell depth via an adjustable energy and a time-modulated intensity course of the laser radiation (9) with a predefinable, reproducible shape factor, and the support layer (13) is applied in a thickness between 1 μm and 15 μm, in particular between 5 μm and 10 μm, specifically by electroplating, with particular attention to a layer thickness tolerance of less than 10⁻³, preferably less than 5·10^{-5.}

5. The method as claimed in one of claims 1 to 4, characterized in that, for the support layer (13), a material with a high vapor pressure, preferably with at least one higher by the factor 5, is selected and in particular the support layer (13) can be removed easily, in particular chemically, without attacking the information-bearing layer regions (8).

6. The method as claimed in one of claims 1 to 5, characterized in that a substantial proportion of the material of the support layer (13) is selected such that it has a low melting point, preferably below that of copper, in particular below 500° C., and is above all a metal, in particular zinc.

7. The method as claimed in one of claims 1 to 6, characterized in that a laser radiation (9) with a preferred wavelength between 0.8 μm and 11 μm, preferably the radiation from a CO₂ laser, is used, in particular the radiation from an Nd:YAG laser in the case of engraved cells in the micrometer range.

8. A base body (1) for a gravure printing form, into whose top surface region or regions (8) engraved cells (5) can be introduced as printing information by time-modulated, in particular pulsed, laser radiation (9), using a method according to claims 1 to 7, characterized in that each top surface region (8) is covered by a removable, preferably single, erosion support layer (13), through which engraved cells (5) can be introduced by the laser radiation (9), and the support layer (13) permits good input coupling of the energy for the laser radiation (9) with good material removal initiation in relation to the material (3) lying underneath with minimized directed radiation backscatter.

9. The base body (1) as claimed in claim 8, characterized in that the layer regions (8) provided for the impression of information are made of copper, and the support layer (13) has a thickness between 1 μm and 15 μm, in particular between 5 μm and 10 μm, with a layer thickness tolerance of less than 10⁻³, in particular less than 5·10⁻⁵, the support layer (13) being a material with a high vapor pressure, preferably with at least one higher by the factor 5 than copper, and in particular the support layer (13) can be removed easily, in particular chemically, without attacking the information-bearing layer regions (8).

10. The base body (1) as claimed in claim 8 or 9, characterized in that a substantial proportion of the material of the support layer (13) has a low melting point, preferably below that of copper, in particular below 500° C., and is above all a metal, in particular zinc.
